(19) United States
(12) Patent Application Publication
(10) Pub. No.: US 2005/0196905 A1
(43) Pub. Date: Sep. 8, 2005

(54) Semiconductor device featuring fine windows formed in oxide layer of semiconductor substrate thereof, and production method for manufacturing such semiconductor device

(75) Inventor: Takayuki Onda, Kawasaki-Shi (JP)

Correspondence Address: YOUNG & THOMPSON, 745 SOUTH 23RD STREET, 2ND FLOOR, ARLINGTON, VA, 22202, US

(73) Assignee: NEC ELECTRONICS CORPORATION, KAWASAKI-SHI (JP)

(21) Appl. No.: 11/060,319

(22) Filed: Feb. 18, 2005

(30) Foreign Application Priority Data
Feb. 20, 2004 (JP) 2004-043804

(51) Int. Cl. H01L 21/48

(52) U.S. Cl. 438/125

(57) ABSTRACT

A semiconductor device includes a semiconductor substrate, and an oxide layer formed thereon. The oxide layer has a window which is formed by forming a peeling-prevention layer on the oxide layer, forming a KrF-ray sensitive photoresist layer on the peeling-prevention layer, forming an opening in the KrF-ray sensitive photoresist layer, performing an anisotropic etching process by using the KrF-ray sensitive photoresist layer as a mask, so that an opening and a recess are respectively formed in the peeling-prevention layer and the oxide layer, and performing a wet etching process by using the peeling-prevention layer as a mask, resulting in formation of the recess of the oxide layer as the window in the oxide layer, whereby a surface area of the semiconductor substrate is exposed by the window.

### BACKGROUND OF THE INVENTION

1. Field of the Invention

The present invention generally relates to a semiconductor device featuring a plurality of fine windows formed in an oxide layer on a semiconductor substrate thereof, and more particularly relates to a nonvolatile semiconductor memory device featuring a plurality of tunnel windows formed in an oxide layer on a semiconductor substrate and covered with tunnel insulating layers. Also, the present invention relates to a production method for manufacturing such a semiconductor device.

2. Description of the Related Art

For example, as a representative of a semiconductor device featuring a plurality of fine windows formed in an oxide layer on a semiconductor substrate, there is a floating gate tunnel oxide (FLOTOX) type nonvolatile semiconductor memory device, such as an electrically-erasable programmable read-only memory (EEPROM), a flash EPROM or the like. In this nonvolatile semiconductor memory device, each of the fine windows is defined as a tunnel window in the oxide layer on the semiconductor substrate, the tunnel window is covered with a thin tunnel insulating layer, and a floating gate electrode is formed on the tunnel insulating layer.

In a prior art production method for manufacturing a nonvolatile semiconductor memory device, the definition of the tunnel windows in the semiconductor substrate is carried out by using a photolithography process and an etching process. As well known, the photolithography process involves an exposure process and a development process for forming a plurality of openings in a photoresist layer formed on the oxide layer on the semiconductor substrate, and each of the openings is provided for forming a corresponding tunnel window in the oxide layer on the semiconductor substrate.

Usually, for the formation of the photoresist layer, an i-ray sensitive photoresist material, which exhibits a photosensitivity to i-rays having a wavelength of 365 nm, is used, and a possible minimum dimension or diameter of the openings, which can be formed in the i-ray sensitive photoresist layer, is determined by the wavelength of the i-rays. Namely, when the i-rays having the wavelength of 365 nm are used, the possible minimum dimension or diameter of the openings is approximately 0.3 μm.

A dimension or diameter of the tunnel windows depends upon the dimension or diameter of the openings of the i-ray sensitive photoresist layer, and become larger than that of the openings, because the tunnel windows are formed in the oxide layer-on the semiconductor substrate by using a wet etching process or isotropic etching process. For example, when each of the openings has the possible minimum dimension or diameter of 0.3 μm, the dimension or diameter of the tunnel window is approximately 0.4 μm.

In particular, in the wet etching process or isotropic etching process, the i-ray sensitive photoresist layer having the openings is used as a mask for the formation of the tunnel windows, and the etching is isotropically spread in the oxide layer on the semiconductor substrate. Namely, the spread of the etching is carried out in both a vertical direction and a horizontal direction, resulting in the formation of the tunnel windows having the dimension or diameter larger than that of the openings.

JP-A-H03-060078 proposes that a dry etching process or anisotropic etching process, such as a reactive ion etching (RIE) process or the like, is used for the formation of the tunnel windows in the oxide layer on the semiconductor substrate. In this case, although the tunnel windows have substantially the same dimension or diameter as that of the openings of the i-ray sensitive photoresist layer, due to the anisotropic etching carried out by the RIE process, a surface area of the semiconductor substrate, which is exposed by each of the tunnel-windows, is subjected to plasma damage during the RIE process.

In order to eliminate the plasma damage from each of the exposed areas of the semiconductor substrate, a silicon dioxide layer is formed as a sacrifice oxide layer on each of the exposed areas of the semiconductor substrate by using an oxidization process, and the sacrifice oxide layer is etched and removed from the each of the exposed areas of the semiconductor substrate by using a wet etching process or isotropic etching process, whereby each of the exposed areas of the semiconductor substrate is free from the plasma damage.

Nevertheless, during the wet etching process for the etching of the sacrifice oxide layer, each of the tunnel windows is somewhat spread in the oxide layer on the semiconductor substrate in the horizontal direction due to the isotropic etching carried out by the wet etching process. Also, in JP-A-H03-060078, although the sacrifice oxide layer is etched from each of the exposed areas of the semiconductor substrate, it is practically impossible to completely eliminate the plasma damage therefrom.

In either event, in the above-mentioned prior art production methods, it is practically impossible to form tunnel windows, having a dimension or diameter of less than 0.4 μm, in the oxide layer on the semiconductor substrate without causing any damage to the semiconductor substrate.

### SUMMARY OF THE INVENTION

Therefore, an object of the present invention is to provide to provide a semiconductor device featuring a plurality of fine windows, having a dimension or diameter of less than 0.4 μm, formed in an oxide layer on a semiconductor substrate thereof.

Another object of the present invention is to provide a production method for manufacturing such as semiconductor device.

In accordance with a first aspect of the present invention, there is provided a semiconductor device comprising a semiconductor substrate, and an oxide layer formed on the semiconductor substrate. The oxide layer has a window which is formed by forming a peeling-prevention layer on the oxide layer, forming a KrF-ray sensitive photoresist layer on the peeling-prevention layer, forming an opening in the KrF-ray sensitive photoresist layer, performing an anisotropic etching process by using the KrF-ray sensitive photoresist layer as a mask, so that an opening and a recess are respectively formed in the peeling-prevention layer and the oxide layer, and performing a wet etching process by using the peeling-prevention layer as a mask, resulting in formation of the recess of the oxide layer as the window in the oxide layer, whereby a surface area of the semiconductor substrate is exposed by the window. The peeling-prevention layer exhibits a superior adhesion property to both the oxide layer and the KrF-ray sensitive photoresist layer.

The opening of the KrF-ray sensitive photoresist layer may feature a dimension of less than 0.3 μm, and the window may feature a dimension of less than 0.4 μm.

The formation of the peeling-prevention layer may be carried out by using a composite resin material which is composed of a polyimide-based polymer component, and a dye component selected from a group consisting of an organic halogen compound, a hydroxyl compound, and a carboxyl compound; Also, the formation of the peeling-prevention layer may be carried out by using a polymer material which is obtained from a triazine-based derivative. Note, of course, another suitable material may be used as the peeling-prevention layer as long as it exhibits a superior adhesion property to both the oxide layer and the KrF-ray sensitive photoresist layer.

In accordance with a second aspect of the present invention, there is provided a production method for manufacturing a semiconductor device, which comprises the steps of: preparing a semiconductor substrate; forming an oxide layer on the semiconductor substrate; forming a peeling-prevention layer on the oxide layer, the peeling-prevention layer exhibiting a superior adhesion property to the oxide layer; forming a KrF-ray sensitive photoresist layer on the peeling-prevention layer, the peeling-prevention layer exhibiting a superior adhesion property to the KrF-ray sensitive photoresist layer; forming an opening in the KrF-ray sensitive photoresist layer; performing an anisotropic etching process by using the KrF-ray sensitive photoresist layer as a mask, so that an opening and a recess are formed in the peeling-prevention layer and the oxide layer, respectively; and performing a wet etching process by using the peeling-prevention layer as a mask, so that the recess of the oxide layer is formed as a window in the oxide layer, whereby a surface area of the semiconductor substrate is exposed by the window.

In accordance with a third aspect of the present invention, there is provided a floating gate tunnel oxide type nonvolatile semiconductor memory device comprising a semiconductor substrate, and an oxide layer formed on the semiconductor substrate. The oxide layer has a tunnel window, which is formed by forming a peeling-prevention layer on the oxide layer, forming a KrF-ray sensitive photoresist layer on the peeling-prevention layer, forming an opening in the KrF-ray sensitive photoresist layer, performing an anisotropic etching process by using the KrF-ray sensitive photoresist layer as a mask, so that an opening and a recess are respectively formed in the peeling-prevention layer and the oxide layer, and performing a wet etching process by using the peeling-prevention layer as a mask, resulting in the formation of the recess of the oxide layer as the tunnel window in the oxide layer, whereby a surface area of the semiconductor substrate is exposed by the window. The peeling-prevention layer exhibits a superior adhesion property to both the oxide layer and the KrF-ray sensitive photoresist layer. The nonvolatile semiconductor memory device further comprises a tunnel insulating layer formed on the exposed surface area of semiconductor substrate.

In this nonvolatile semiconductor memory device, the semiconductor substrate may have a drain region formed therein, and the exposed surface area of semiconductor substrate may form a part of the drain region. Also, the semiconductor substrate may have a source region formed therein, and the exposed surface area of semiconductor substrate may form a part of the source region. Further, the semiconductor substrate may have a source region, a drain region, and a channel region which are formed therein and associated with each other, and the exposed surface area of semiconductor substrate may form the channel region.

The nonvolatile semiconductor memory device may further comprise a floating gate electrode formed on the tunnel insulating layer, an insulating interlayer formed on the oxide layer including the floating gate electrode, and a control gate electrode formed on the insulating interlayer so as to cover the floating gate electrode.

In the nonvolatile semiconductor memory device, the opening of the KrF-ray sensitive photoresist layer may feature a dimension of less than 0.3 μm, and the tunnel window may feature a dimension of less than 0.4 μm.

The formation of the peeling-prevention layer may be carried out by using a composite resin material which is composed of a polyimide-based polymer component, and a dye component selected from a group consisting of an organic halogen compound, a hydroxyl compound, and a carboxyl compound. Also, the formation of the peeling-prevention layer may be carried out by using a polymer material which is obtained from a triazine-based derivative. Note, of course, another suitable material may be used as the peeling-prevention layer as long as it exhibits a superior adhesion property to both the oxide layer and the KrF-ray sensitive photoresist layer.

In accordance with a fourth aspect of the present invention, there is provided a production method for manufacturing a floating gate tunnel oxide type nonvolatile semiconductor memory device, which comprises the steps of; preparing a semiconductor substrate; forming an oxide layer on the semiconductor substrate; forming a peeling-prevention layer on the oxide layer, the peeling-prevention layer exhibiting a superior adhesion property to the oxide layer; forming a KrF-ray sensitive photoresist layer on the peeling-prevention layer, the peeling-prevention layer exhibiting a superior adhesion property to the KrF-ray sensitive photoresist layer; forming an opening in the KrF-ray sensitive photoresist layer; performing an anisotropic etching process by using the KrF-ray sensitive photoresist layer as a mask, so that an opening and a recess are respectively formed in the peeling-prevention layer and the oxide layer; performing a wet etching process by using the peeling-prevention layer as a mask, so that the recess of the oxide layer is formed as a tunnel window in the oxide layer, whereby a surface area of the semiconductor substrate is exposed by the tunnel window; and forming a tunnel insulating layer on the exposed surface area of semiconductor substrate.

### BRIEF DESCRIPTION OF THE DRAWINGS

The above object and other objects will be more clearly understood from the description set forth below, with reference to the accompanying drawings, wherein:

FIG. 1A is a partial cross-sectional view of a semiconductor substrate, showing a first representative step of a first prior production method for manufacturing a nonvolatile semiconductor memory device;

FIG. 1B is a partial cross-sectional view, similar to FIG. 1A, showing a second representative step of the first prior art production method;

FIG. 1C is a partially-enlarged cross-sectional view of FIG. 1B, on which a patterned i-ray sensitive photoresist layer is formed on the semiconductor substrate, showing a third representative step of the first prior art production method;

FIG. 1D is a partially-enlarged cross-sectional view, similar to FIG. 1C, showing a fourth representative step of the first prior art production method;

FIG. 1E is a partially-enlarged cross-sectional view, similar to FIG. 1D, showing a fifth representative step of the first prior art production method;

FIG. 1F is a partially-enlarged cross-sectional view, similar to FIG. 1E, showing a sixth representative step of the first prior art production method;

FIG. 1G is a partial cross-sectional view of the semiconductor substrate, on which a tunnel insulating layer, a floating gate electrode, an insulating interlayer, and a control gate electrode are formed in order thereon, showing a seventh representative step of the prior art production method;

FIG. 2 is an electron microscope photograph of a nonvolatile semiconductor memory device, corresponding to a part of FIG. 1G, which is manufactured in accordance with the first prior art production method;

FIG. 3A is a partial cross-sectional view of a semiconductor substrate, showing a first representative step of a second prior production method for manufacturing a nonvolatile semiconductor memory device;

FIG. 3B is a partial cross-sectional view, similar to FIG. 3A, showing a second representative step of the second prior art production method;

FIG. 3C is a partially-enlarged cross-sectional view of FIG. 3B, on which a patterned i-ray sensitive photoresist layer is formed on the semiconductor substrate, showing a third representative step of the second prior art production method;

FIG. 3D is a partially-enlarged cross-sectional views similar to FIG. 3C, showing a fourth representative step of the second prior art production method;

FIG. 3E is a partially-enlarged cross-sectional view, similar to FIG. 3D, showing a fifth representative step of the second prior art production method;

FIG. 3F is a partially-enlarged cross-sectional view, similar to FIG. 3E, showing a sixth representative step of the second prior art production method;

FIG. 3G is a partially-enlarged cross-sectional view, similar to FIG. 3F, showing a seventh representative step of the second prior art production method;

FIG. 3H is a partial cross-sectional view of the semiconductor substrate, on which a tunnel insulating layer, a floating gate electrode, an insulating interlayer, and a control gate electrode are formed in order thereon, showing an eighth representative step of the prior art production method;

FIG. 4A is an electron microscope photograph showing a silicon substrate, and a KrF-ray sensitive photoresist layer formed on the silicon substrate and having an opening formed therein;

FIG. 4B is a partially-enlarged photograph of the electron microscope photograph of FIG. 4A;

FIG. 5A is a partial cross-sectional view of a semiconductor substrate, showing a first representative step of a production method for manufacturing a nonvolatile semiconductor memory device according to the present invention;

FIG. 5B is a partial cross-sectional view, similar to FIG. 5A, on which a silicon dioxide layer, a peeling-prevention layer, and a KrF-ray sensitive photoresist layer are formed in order on the semiconductor substrate, showing a second representative step of the production method according to the present invention;

FIG. 5C is a partially-enlarged cross-sectional view of FIG. 5B, in which an opening is formed in the KrF-ray sensitive photoresist layer, showing a third representative step of the production method according to the present invention;

FIG. 5D is a partially-enlarged cross-sectional view, similar to FIG. 5C, showing a fourth representative step of the production method according to the present invention;

FIG. 5E is a partially-enlarged cross-sectional view, similar to FIG. 5D, showing a fifth representative step of the production method according to the present invention;

FIG. 5F is a partially-enlarged cross-sectional view, similar to FIG. 5E, showing a sixth representative step of the production method according to the present invention;

FIG. 5G is a partial cross-sectional view of the semiconductor substrate, in which a floating gate electrode is defined on a tunnel insulating layer, showing a seventh representative step of the production method according to the present invention;

FIG. 5H is a partial cross-sectional view of the semiconductor substrate, similar to FIG. 5G, showing an eighth representative step of the production method according to the present invention;

FIG. 6A is an electron microscope photograph showing a silicon substrate, a silicon dioxide layer formed on the silicon substrate, a peeling-prevention layer formed on silicon dioxide layer, and a KrF-ray sensitive photoresist layer formed on the peeling-prevention layer, the silicon dioxide layer being formed with a tunnel window according to the present invention;

FIG. 6B is a partially-enlarged photograph of the electron microscope photograph of FIG. 6A; and

FIG. 7 is a partial cross-sectional view of a semiconductor substrate of another type nonvolatile semiconductor memory device, which may be manufactured by the production method according to the present invention.

### DESCRIPTION OF THE PREFERRED EMBODIMENTS

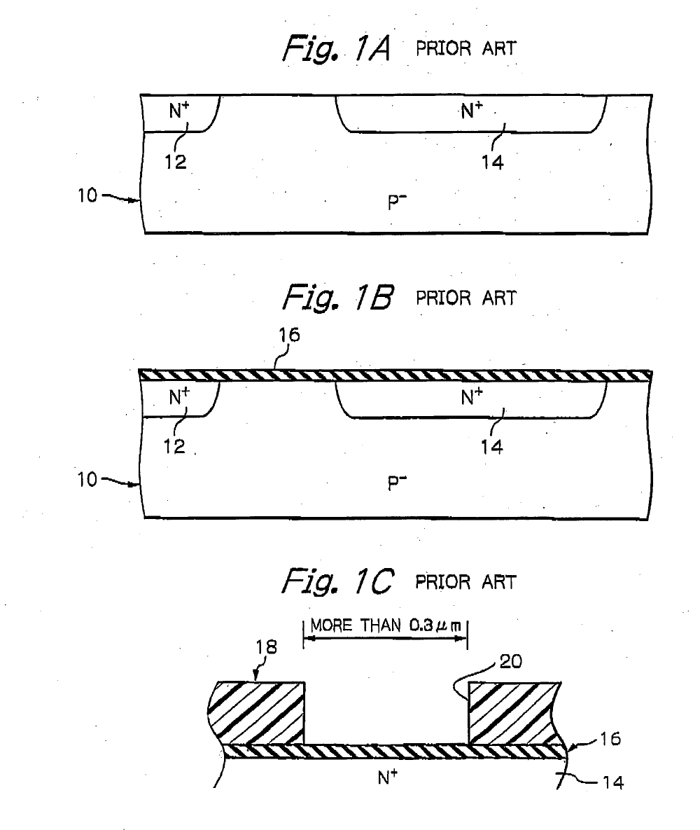

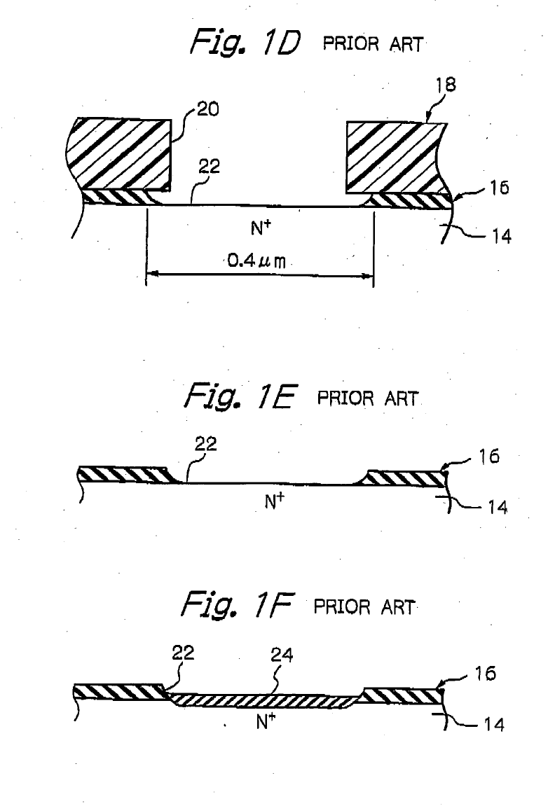

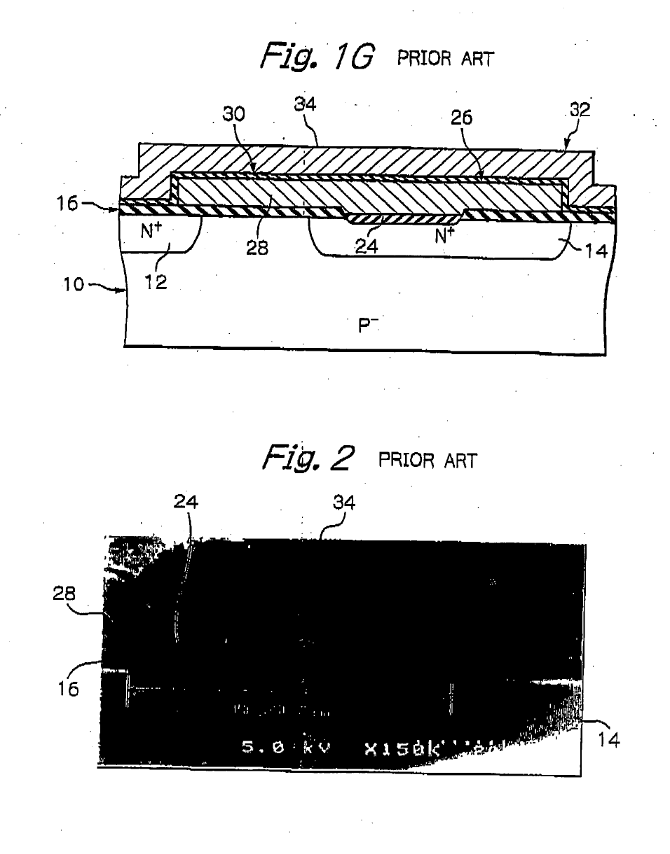

Before descriptions of an embodiment of the present invention, for better understanding of the present invention, a first prior art production method for manufacturing a floating gate tunnel oxide (FLOTOX) type nonvolatile semiconductor memory device will be now explained with reference to FIGS. 1A to 1G.

First, as shown in FIG. 1A, a P⁻-type semiconductor substrate 10, which is derived from, for example, a monocrystalline silicon wafer, is prepared. A surface of the semiconductor substrate 10 is sectioned into a plurality of chip areas by forming grid-like fine grooves (i.e. scribe lines) therein. Also, a plurality of element-isolation layers (not shown) are formed in each of the chip areas on the semiconductor substrate 10 by using a TSI (shallow-trench isolation) method or a LOCOS (local oxidation of silicon) method, so that a plurality of element-formation areas are defined on a surface of each of the chip areas. Note, in FIG. 1A, one of the element-formation areas, which forms a part of a memory cell to be produced in the semiconductor substrate 10, is partially illustrated in a cross-sectional view.

After the definition of the element-formation areas in each of the chip areas is completed, as shown in FIG. 1A, an N⁺-type source region 12 and an N⁺-type drain region 14 are formed in each of the element-formation areas on the semiconductor substrate 10 by using various well-known processes.

Then, the semiconductor substrate 10 is subjected to a thermal oxidization process such that a silicon dioxide layer 16 is formed on the surface of the semiconductor substrate 10, as shown in FIG. 1B. Note, for example, the silicon dioxide layer 16 may have a thickness falling within a range from 20 nm to 30 nm.

After the formation of the silicon dioxide layer 16 is completed, as shown in FIG. 1C, an i-ray sensitive photoresist layer 18 is formed on the silicon dioxide layer 16, and is patterned by using a photolithography process and an etching process such that a plurality of openings 20 are formed in the i-ray sensitive photoresist layer 18. Note, each of the openings 20 is provided for defining a tunnel window in the silicon dioxide layer 16, and is positioned above a corresponding drain region 14, as shown in FIG. 1C.

The aforesaid photolithography process involves an i-ray exposure process and a development process for forming the openings 20 in the i-ray sensitive photoresist layer 18, and i-rays having a wavelength of 365 nm are used in the i-ray exposure process, A possible minimum dimension or diameter of the openings 20 depends upon the wavelength (365 nm) of the i-rays, and is approximately 0.3 μm (FIG. 1C). Namely, it is impossible to form openings, having a dimension or diameter of less than 0.3 μm, in the i-ray sensitive photoresist layer 18.

After the formation of the patterned i-ray sensitive photoresist layer 18 is completed, the semiconductor substrate 10 is subjected to a wet etching process or isotropic etching process by using a suitable etching solution, such as a buffered hydrofluoric acid solution or the like, and thus a plurality of tunnel windows 22 are formed in the silicon dioxide layer 16 by using the patterned i-ray sensitive photoresist layer 18 as a mask, as shown in FIG. 1D. Note, in this drawing, only one of the tunnel windows 22 is representatively illustrated. In short, the material of the silicon dioxide layer 16 is etched and removed from an area of the silicon dioxide layer 16 which is exposed by each of the openings 20, resulting in the formation of the tunnel window 22.

In the wet etching process or isotropic etching process, a dimension or diameter of the tunnel window 22 necessarily become larger than the dimension or diameter of each of the openings 20, because the etching is isotropically spread in the silicon dioxide layer 16. Namely, the spread of the etching is carried out in both a vertical direction and a horizontal direction, resulting in the formation of the tunnel window 22 having the dimension or diameter larger than that (0.3 μm) of the opening 20, as shown in FIG. 1D.

In addition, in the wet etching process, it is necessary to set an etching time longer than a usual etching time which is calculated from an etching rate based on the etching solution used, before the material forming the silicon dioxide layer 16 can be completely removed from each of the tunnel windows 22. Thus, the etching is further spread in the silicon dioxide layer 16 in the horizontal direction. As a result, in this first prior art production process, the dimension or diameter of the tunnel window 22 may be more than 0.4 μm.

After the formation of the tunnel windows 22 is completed, the patterned i-ray sensitive photoresist layer or mask 18 is removed from the silicon dioxide layer 16, as shown in FIG. 1E. The removal of the mask 18 may be carried out by an oxygen-plasma ashing process, a wet peeling process using an organic peeling solution, and so on. Subsequently, the semiconductor substrate 10 is subjected to a thermal oxidization process such that a silicon dioxide layer 24 is formed as a tunnel insulating layer on an area of the drain region 14 which is exposed by each of the tunnel windows 22, as shown in FIG. 1F.

After the formation of the silicon dioxide layer or tunnel insulating layers 24 is completed, as shown in FIG. 1G, a polycrystalline silicon layer 26 is formed on the silicon dioxide layer 16 including the tunnel insulating layers 24, by using a suitable chemical vapor deposition (CVD) process, and then suitable impurities are implanted and diffused in the polycrystalline silicon layer 26, by using various well-known processes.

Then, the polycrystalline silicon layer 26 is patterned by using a photolithography process and an etching process, so that a plurality of floating gate electrodes 28 are defined on the silicon dioxide layer 16. As shown in FIG. 1G, each of the floating gate electrodes 28 is positioned so as to be in contact with a corresponding drain region 14 through the intermediary of a corresponding tunnel insulating layer 24, and extends so as to bridge a space between the adjacent source and drain regions 12 and 14. Note, in FIG. 1G, only one of the floating gate electrodes 28 is representatively illustrated.

After the definition of the floating gate electrodes 28 is completed, an insulating interlayer 30 is formed over the silicon dioxide layer 16 and the floating gate electrodes 28, as shown in FIG. 1G. The insulating interlayer 30 may be defined as a multi-layered insulating layer composed of a first silicon dioxide layer section, a silicon nitride layer section, and a second silicon dioxide layer formed in order on the silicon dioxide layer 16 and the floating gate electrodes 28. Note, the formation of the multi-layered insulating interlayer 30 may be carried out by using a suitable CVD process.

After the formation of the insulating interlayer 30 is completed, as shown in FIG. 1G, a polycrystalline silicon [symbol] over the insulating interlayer 38 by using a suitable CVD process, and then suitable impurities are implanted and diffused in the polycrystalline silicon layer 32, by using various well-known processes. Then, the polycrystalline silicon layer 32 is patterned by using a photolithography process and an etching process, so that a plurality of control gate electrodes 34 are defined on the insulating interlayer 30. As shown in FIG. 1G, each of the control gate electrodes 34 is positioned so as to cover a corresponding floating gate electrode 28. Note, in FIG. 1G, only one of the control gate electrodes 34 is representatively illustrated.

Thereafter, the semiconductor substrate 10 is subjected to various processes for forming a multi-layered wiring arrangement thereon, and is then subjected to a dicing process, in which it is cut along the scribe lines, whereby the nonvolatile semiconductor memory devices are separated from each other, resulting in the production of the nonvolatile semiconductor memory devices.

Although there is a demand for further advances in integration of nonvolatile semiconductor memory devices in this field, the further advance of the integration cannot be carried out by the above-mentioned first prior art production method, because the tunnel windows 22 cannot have the dimension or diameter of less than 0.4 μm, as discussed hereinbefore.

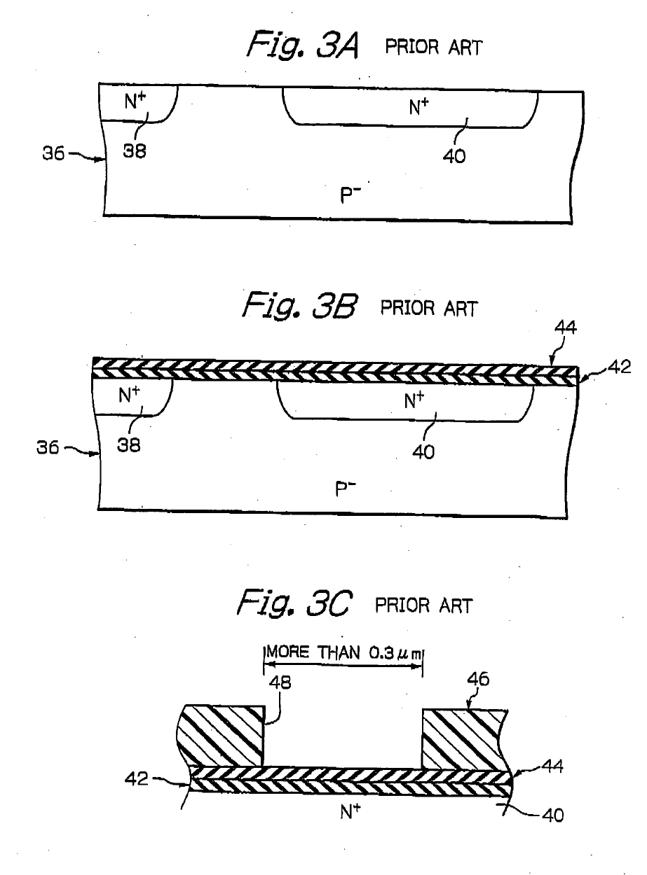

FIG. 2 shows an electron microscope photograph of a nonvolatile semiconductor memory device manufactured in accordance with the above-mentioned first prior art production method. This electron microscope photograph corresponds to a part of the cross-sectional view shown in FIG. 1G, and the features similar to those of FIG. 1G are indicated by the same references in FIG. 2. As is apparent from the electron microscope photograph of FIG. 2, the tunnel insulating layer 24 has a dimension or diameter of 0.5 μm.

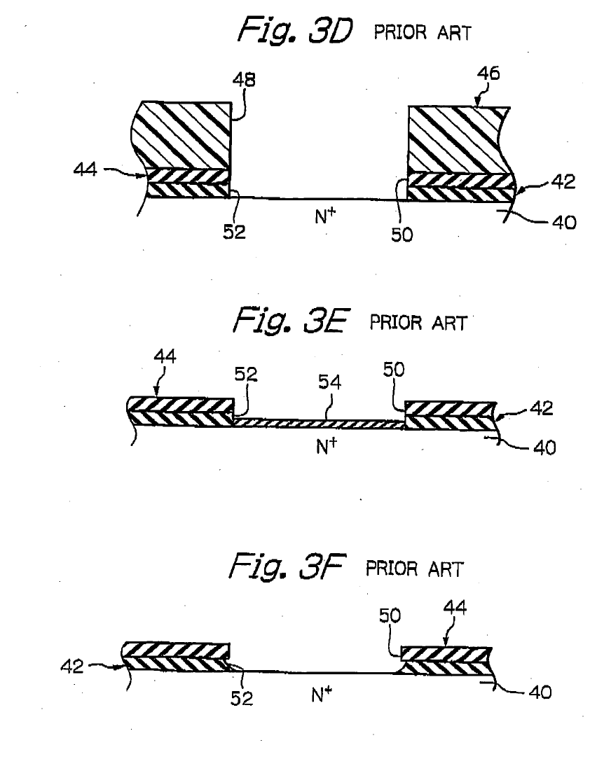

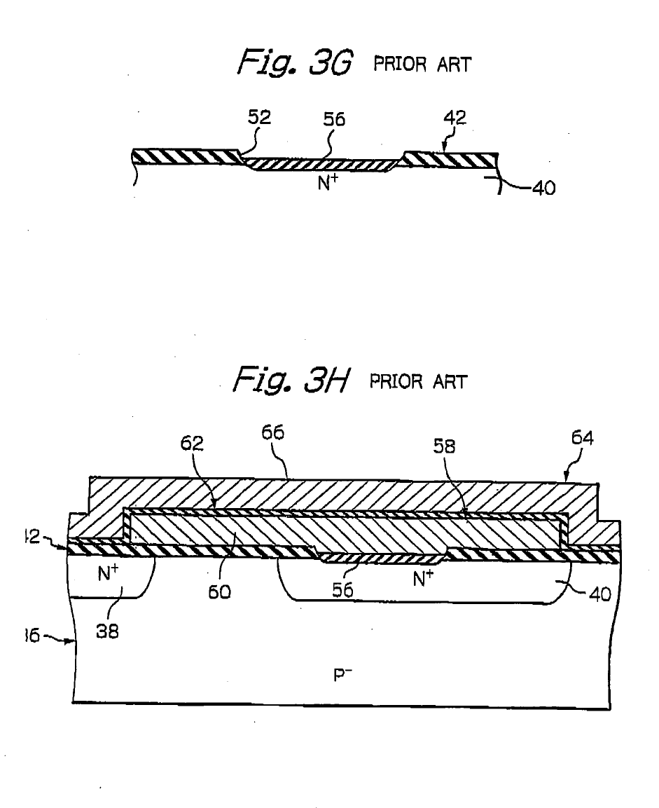

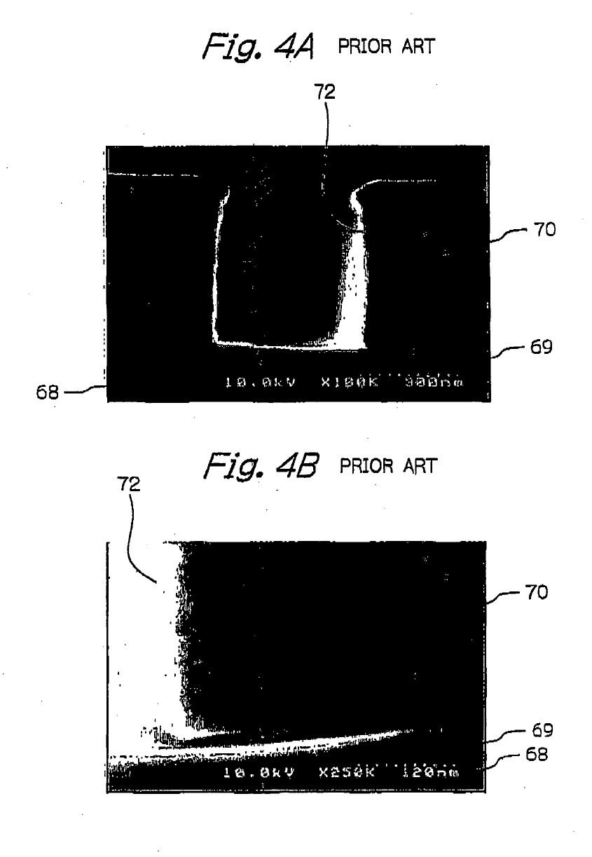

With reference to FIGS. 3A to 3G, a second prior art production method for manufacturing a FLOTOX type nonvolatile semiconductor memory device is explained below. Note, this second prior art production method is disclosed in, for example, in JP-A-H03-060078.

As shown in FIG. 3A, a P⁻-type semiconductor substrate 36, which is derived from a monocrystalline silicon wafer, is prepared. Similar to the above-mentioned first prior art production method, a surface of the semiconductor substrate 36 is sectioned into a plurality of chip areas by forming grid-like fine grooves (i.e. scribe lines) therein, and a plurality of element-isolation layers (not shown) are formed in each of the chip areas on the semiconductor substrate 36 by using a TSI method or a LOCOS method, so that a plurality of element-formation areas are defined on a surface of each of the chip areas. Note, similar to FIG. 1A, in FIG. 3A, one of the element-formation areas, which forms a part of a memory cell to be produced in the semiconductor substrate 36, is partially illustrated in a cross-sectional view.

After the definition of the element-formation areas in each of the chip areas is completed, as shown in FIG. 3A, an N⁺-type source region 38 and an N⁺-type drain region 40 are formed in each of the element-formation areas of the semiconductor substrate 36 by using various well-known processes.

Then, the semiconductor substrate 36 is subjected to a thermal oxidization process, such that a silicon dioxide layer 42 is formed on the surface of the semiconductor substrate 36, as shown in FIG. 3B. Subsequently, a silicon nitride layer 44 is formed on the silicon dioxide layer 42 by using a suitable CVD process. Note, similar to the above-mentioned first prior production method, the silicon dioxide layer 42 may have a thickness of 20 nm to 30 nm.

After the formation of the silicon nitride layer 44 is completed, as shown in FIG. 3C, an i-ray sensitive photoresist layer 46 is formed on the silicon nitride layer 44, and is patterned by using a photolithography process and an etching process such that a plurality of openings 48 are formed in the i-ray sensitive photoresist layer 46. Note, each of the openings 48 is provided for defining a tunnel window in the silicon dioxide layer 42, and is positioned above a corresponding drain region 40, as shown in FIG. 3C.

Similar to the above-mentioned first prior art production method, the photolithography process involves an i-ray exposure process and a development process for forming the openings 48 in the i-ray sensitive photoresist layer 46, and the i-rays having the wavelength of 365 nm are used in the i-ray exposure process. Thus, a possible minimum dimension or diameter of the openings 48 is approximately 0.3 μm. In other words, in the second prior art production method, it is also impossible to form openings, having a dimension or diameter of less than 0.3 μm, in the i-ray sensitive photoresist layer 46.

After the formation of the patterned i-ray sensitive photoresist layer 46 is completed, the semiconductor substrate 36 is subjected to a dry etching process or anisotropic etching process, such as a reactive ion etching (RIE) process or the like, and thus a plurality of openings 50 and a plurality of tunnel windows 52 are formed in the respective silicon nitride layer 44 and silicon dioxide layer 4Z by using the patterned i-ray sensitive photoresist layer 46 as a mask, as shown in FIG. 3D. After the formation of the openings 50 and tunnel windows 52 is completed, the patterned i-ray sensitive photoresist layer or mask 46 is removed from the semiconductor substrate 36.

In this second prior art production method, both the opening 50 and the tunnel window 52 associated with each other have substantially the same dimension or diameter as that of 40, which are exposed by the tunnel windows 52, is subjected to plasma damage during the RIE process.

In order to eliminate the plasma damage from each of the exposed areas of the drain regions 40, the semiconductor substrate 36 is subjected to a thermal oxidization process, in which a silicon dioxide layer 54 is formed as a sacrifice oxide layer on each of the exposed areas of the drain regions 40, as shown in FIG. 3E. Namely, a surface section of each of the exposed areas of the drain regions 40, subjected to the plasma damage, is formed as the sacrifice oxide layer 54 by the thermal oxidization process.

Then, the semiconductor substrate 36 is subjected to a wet etching process or isotropic etching process, using a suitable etching solution, such as a buffered hydrofluoric acid solution or the like, and thus the silicon dioxide layer or sacrifice oxide layer 54 is etched from each of the exposed areas of the drain regions 40 by using the silicon nitride layer 44 (having the openings 50) as a mask, as shown in FIG. 3F. Thus, due to the etching of the sacrifice oxide layer 54, each of the exposed areas of the drain regions 40 is free from the plasma damage.

After the etching of the sacrifice oxide layer 54 is completed, the silicon nitride layer 44 is removed from the silicon dioxide layer 42, and then the semiconductor substrate 36 is again subjected to a thermal oxidization process, in which a silicon dioxide layer 56 is formed as a tunnel insulating layer on each of the exposed areas of the drain regions 40, as shown in FIG. 3G.

Similar to the above-mentioned first production method, after the formation of the silicon dioxide layers or tunnel insulating layers 56 is completed, as shown in FIG. 3H, a polycrystalline silicon layer 58 is formed on the silicon dioxide layer 42 including the tunnel insulating layers 24, by using a suitable CVD process, and then suitable impurities are implanted and diffused in the polycrystalline silicon layer 58, by using various well-known processes.

Then, the polycrystalline silicon layer 58 is patterned by using a photolithography process and an etching process, so that a plurality of floating gate electrodes 60 are defined on the silicon dioxide layer 42 including the tunnel insulating layers 56. As shown in FIG. 3H, each of the floating gate electrodes 60 is positioned so as to be in contact with a corresponding drain region 40 through the intermediary of a corresponding tunnel insulating layer 56, and extends so as to bridge a space between the adjacent source and drain regions 38 and 40. Note, in FIG. 3H, only one of the floating gate electrodes 60 is representatively illustrated.

After the definition of the floating gate electrodes 60 is completed, an insulating interlayer 62 is formed over the silicon dioxide layer 42 and the floating gate electrodes 60, as shown in FIG. 3H. Similar to the insulating interlayer 30 shown in FIG. 1G, the insulating interlayer 62 may be defined as a multi-layered insulating layer composed of a first silicon dioxide layer section, a silicon nitride layer section, and a second silicon dioxide layer formed in order on the silicon dioxide layer 42 and the floating gate electrodes 60. Note, it is possible to carry out the formation of the multi-layered insulating interlayer 62 by using a suitable CVD process.

After the formation of the insulating interlayer 62 is completed, as shown in FIG. 3H, a polycrystalline silicon layer 64 is further formed over the insulating interlayer 62 by using a suitable CVD process, and then suitable impurities are implanted and diffused in the polycrystalline silicon layer 62, by using various well-known processes. Then, the polycrystalline silicon layer 64 is patterned by using a photolithography process and an etching process, so that a plurality of control gate electrodes 66 are defined on the insulating interlayer 62. As shown in FIG. 3H, each of the control gate electrodes 66 is positioned so as to cover a corresponding floating gate electrode 60. Note, in FIG. 3H, only one of the control gate electrodes 66 is representatively illustrated.

Thereafter, the semiconductor substrate 36 is subjected to various processes for forming a multi-layered wiring arrangement thereon, and is then subjected to a dicing process, in which it is cut along the scribe lines, whereby the nonvolatile semiconductor memory devices are separated from each other, resulting in the production of the nonvolatile semiconductor memory devices.

In this second prior art production method, during the wet etching process for the etching of the sacrifice oxide layer 54 (FIG. 3F), each of the tunnel windows 52 is somewhat spread in the silicon dioxide layer 42 in the horizontal direction due to the isotropic etching carried out by the wet etching process, but the spread of the tunnel windows 52 is smaller than the spread of the tunnel windows 22 obtained in the above-mentioned first prior art production method (FIGS. 1A to 1G). Nevertheless, in this second prior art production method, a dimension or diameter of the tunnel windows 52 falls within a range from 0.6 μm to 0.8 μm, as disclosed in JP-A-H03-060078.

Also, in the second prior art production method, although the sacrifice oxide layer 54 is formed on each of the exposed areas of the drain regions 40 (FIG. 3E), and although it is etched therefrom by the wet etching process (FIG. 3F), it is practically impossible to completely eliminate the plasma damage from each of the exposed areas of the drain regions 40.

In the above-mentioned first prior art production method, before each of the tunnel windows 22 having a dimension or diameter of less than 0.4 μm can be formed in the silicon dioxide layer 16 on a semiconductor substrate 10, it is necessary to substitute another photoresist layer for the i-ray sensitive photoresist layer 18. In other words, the photoresist layer (18) must be composed of a photoresist material exhibiting a photosensitivity to rays having a wavelength which is shorter than that (365 nm) of the i-rays, before an opening having a dimension or diameter of less than 0.3 μm can be formed in the photoresist layer (18).

For example, for such a photoresist material, there is a KrF-ray sensitive photoresist material, which exhibits a photosensitivity to KrF rays having a wavelength of 248 nm. In short, it is possible to form the opening having the dimension or diameter of less than 0.3 μm in a KrF-ray sensitive photoresist layer composed of the KrF-ray sensitive photoresist material.

Nevertheless, in the above-mentioned first prior art production method, it is impossible to substitute use the KrF-ray sensitive photoresist layer for the i-ray sensitive photoresist layer 18, because the KrF-ray sensitive photoresist layer exhibits an inferior adhesion property to a silicon dioxide layer (16). Namely, the KrF-ray sensitive photoresist layer may be easily peeled from the silicon dioxide layer (16) during the wet etching process in the first prior art, as shown in electron microscope photographs of FIGS. 4A and 4B.

In the electron microscope photographs of FIGS. 4A and 4B, reference 68 indicates a silicon substrate; reference 69 indicates a silicon dioxide layer formed on the silicon substrate 68; reference 70 indicates a KrF-ray sensitive photoresist layer formed on the silicon dioxide layer 69, and reference 72 indicates an opening formed in the KrF-ray sensitive photoresist layer 70. As best shown in the electron microscope photograph of FIG. 4B, the KrF-ray sensitive photoresist layer 70 is partially peeled from the silicon dioxide layer 69. Thus, in the above-mentioned first prior art production method, it is impossible to use the KrF-ray sensitive photoresist layer (70).

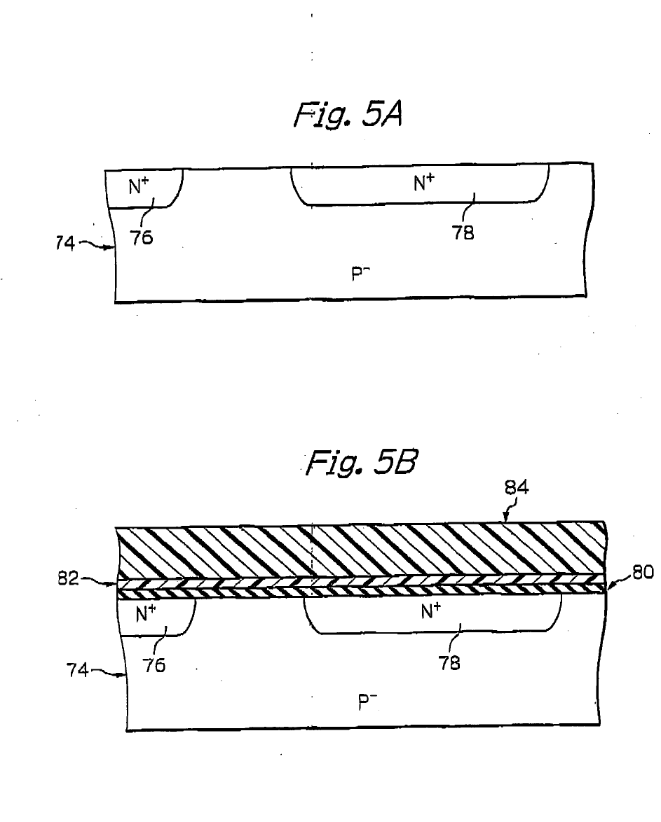

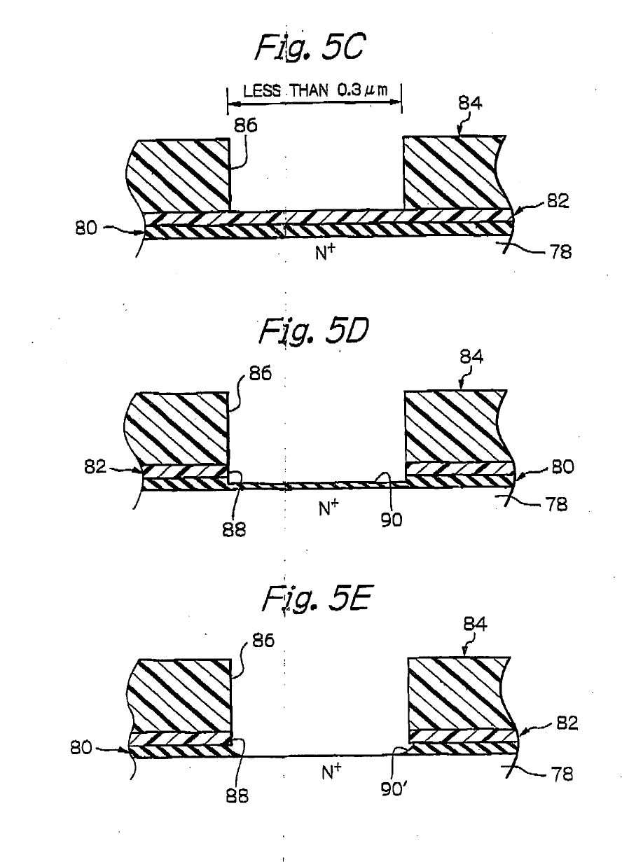

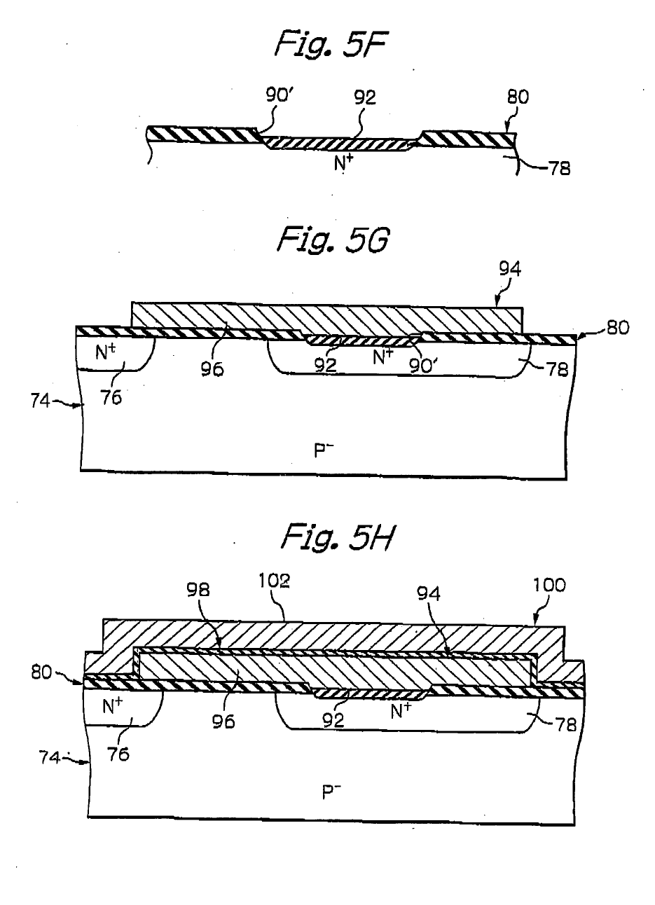

Next, with reference to FIG. 5A to 5E, an embodiment of a production method for manufacturing a FLOTOX type nonvolatile semiconductor memory device according to the present invention is explained below.

First, as shown in FIG. 5A, a P⁻-type semiconductor substrate 74, which is derived from, for example, a monocrystalline silicon wafer, is prepared. A surface of the semiconductor substrate 74 is sectioned into a plurality of chip areas by forming grid-like fine grooves (i.e. scribe lines) therein. Also, a plurality of element-isolation layers (not shown) are formed in each of the chip areas on the semiconductor substrate 74 by using a TSI method or a LOCOS method, so that a plurality of element-formation areas are defined on a surface of each of the chip areas. Note, in FIG. 5A, one of the element-formation areas, which forms a part of a memory cell to be produced in the semiconductor substrate 74, is partially illustrated in a cross-sectional view.

After the definition of the element-formation areas in each of the chip areas is completed, as shown in FIG. 5A, an N⁺-type source region 76 and an N⁺-type drain region 78 are formed in each of the element-formation areas of the semiconductor substrate 74 by using various well-known processes.

After the formation of the source and drain regions 76 and 78 is completed, the semiconductor substrate 74 is subjected to a thermal oxidization process, such that a silicon dioxide layer 80 is formed on the surface of the semiconductor substrate 74, as shown in FIG. 5B. Note, the silicon dioxide layer 80 may have a thickness of 20 nm to 30 nm. Subsequently, a peeling-prevention layer 82 is formed on the silicon dioxide layer 80 by using a suitable coating process, and then a KrF-ray sensitive photoresist layer 84 is formed on the peeling-prevention layer 82.

The peeling-prevention layer 82 is composed of a suitable resin material exhibiting a superior adhesion property to both the silicone dioxide layer 80 and the KrF-ray sensitive photoresist layer 84, and the KrF-ray sensitive photoresist layer 84 is composed of a KrF-ray sensitive photoresist material, which exhibits a photosensitivity to KrF rays having a wavelength of 248 nm.

For example, for the peeling-prevention layer 82, it is possible to use a composite resin material which is composed of a polyimide-based polymer component, and a dye component, such as organic halogen compound, hydroxyl compound, carboxyl compound or the like. Also, a polymer material which is obtained from a triazine-based derivative may be used for the peeling-prevention layer 82. Note, each of the aforesaid composite resin material and the aforesaid polymer material is well known as a reflection-prevention material, which is frequently used to form a reflection-prevention layer in the photolithography field.

Of course, another suitable material may be used as the peeling-prevention layer 82 as long as it exhibits a superior adhesion property to both the silicone dioxide layer 80 and the KrF-ray sensitive photoresist layer 84.

As discussed above, when the KrF-ray sensitive photoresist layer 84 is directly formed on the silicon dioxide layer 80, it may be easily peeled from the silicon dioxide layer 80. However, according to the production method according to the present invention, it is possible to securely fix the KrF-ray sensitive photoresist layer 84 on the silicon dioxide layer 80, due to the existence the peeling-prevention layer 82 intervening therebetween.

After the formation of the KrF-ray sensitive photoresist layer 84 on the peeling-prevention layer 82 is completed, the KrF-ray sensitive photoresist layer 84 is patterned by using a photolithography process and an etching process such that a plurality of openings 86 are formed in the KrF-ray sensitive photoresist layer 84. Each of the openings 86 is provided for defining a tunnel window in the silicon dioxide layer 80, and is positioned above a corresponding drain region 78, as shown in FIG. 5C. The photolithography process involves a KrF-ray exposure process and a development process for forming the openings 86 in the KrF-ray sensitive photoresist layer 84. It is possible to give a setting of less than 0.3 μm to a dimension or diameter of the openings 86, due to the wavelength (248 nm) of the KrF-rays used in the KrF-ray exposure process.

After the formation of the patterned KrF-ray sensitive photoresist layer 84 is completed, as shown in FIG. 5D, the semiconductor substrate 74 is subjected to a dry etching process or anisotropic etching process, such as a RIE process or the like, and thus a plurality of openings 88 and a plurality of recesses 90 are formed in the respective peeling-prevention layer 82 and silicon dioxide layer 80 by using the patterned KrF-ray sensitive photoresist layer 84 as a mask, Namely, as is apparent from FIG. 5D, during the anisotropic etching process, a surface area of the silicon dioxide layer 80, which is exposed by each of the openings 88, is partially etched for the formation of the recesses 90, and thus each of the drain regions 78 cannot be subjected to any plasma damage. Both the opening 88 and the recess 90 associated with each other have substantially the same dimension or diameter as that of the opening 86 of the patterned KrF-ray sensitive photoresist layer or mask 84, due to the anisotropic etching carried out by the RIE process.

Subsequently, the semiconductor substrate 74 is subjected to a wet etching process or isotropic etching process, using a suitable etching solution, such as a buffered hydrofluoric acid solution or the like, and thus the silicon dioxide layer 80 is etched at the locations of the recesses 90 by using the peeling-prevention layer 82 (having the openings 88) as a mask, such that each of the recesses 90 is defined as a tunnel window 90′, as shown in FIG. 5E. Namely, an area of each of the drain regions 78 is partially exposed to outside by a corresponding tunnel window 90′.

Each of the tunnel windows 90′ is somewhat spread in the silicon dioxide layer 80 in a horizontal direction due to the isotropic etching carried out by the wet etching process. Thus, a dimension or diameter of the tunnel windows 90′ is somewhat larger than that of a corresponding recess 90, but it is less than 0.4 μm.

After the wet etching process or isotropic etching process is completed, the patterned KrF-ray sensitive photoresist layer 84 and the peeling-prevention layer 82 are removed from the silicon dioxide layer 80, and then the semiconductor substrate 74 is subjected to a thermal oxidization process, in which a silicon dioxide layer 92 is formed as a tunnel insulating layer on each of the exposed areas of the drain regions 78, as shown in FIG. 5F.

After the formation of the silicon dioxide layers or tunnel insulating layers 92 is completed, as shown in FIG. 5G, a polycrystalline silicon layer 94 is formed on the silicon dioxide layer 80 including the tunnel insulating layers 92, by using a suitable CVD process, and then suitable impurities are implanted and diffused in the polycrystalline silicon layer 94, by using various well-known processes.

Then, the polycrystalline silicon layer 94 is patterned by using a photolithography process and an etching process, so that a plurality of floating gate electrodes 96 are defined on the silicon dioxide layer 80 including the tunnel insulating layers 92. As shown in FIG. 5G, each of the floating gate electrodes 96 is positioned so as to be in contact with a corresponding drain region 78 through the intermediary of a corresponding tunnel insulating layer 92, and extends so as to bridge a space between the adjacent source and drain regions 76 and 78. Note, in FIG. 5G, only one of the floating gate electrodes 96 is representatively illustrated.

After the definition of the floating gate electrodes 96 is completed, an insulating interlayer 98 is formed over the silicon dioxide layer 80 and the floating gate electrodes 96, as shown in FIG. 5H. The insulating interlayer 98 may be defined as a multi-layered insulating layer composed of a first silicon dioxide layer section, a silicon nitride layer section, and a second silicon dioxide layer formed in order on the silicon dioxide layer 80 and the floating gate electrodes 96. Note, it is possible to carry out the formation of the multi-layered insulating interlayer 98 by using a suitable CVD process.

After the formation, of the insulating interlayer 98 is completed, as shown in FIG. 5H, a polycrystalline silicon layer 100 is further formed over the insulating interlayer 98 by using a suitable CVD process, and then suitable impurities are implanted and diffused in the polycrystalline silicon layer 100, by using various well-known processes. Then, the polycrystalline silicon layer 100 is patterned by using a photolithography process and an etching process, so that a plurality of control gate electrodes 102 are defined on the insulating interlayer 98. As shown in FIG. 5H, each of the control gate electrodes 102 is positioned so as to cover a corresponding floating gate electrode 96. Note, in FIG. 5H, only one of the control gate electrodes 102 is representatively illustrated.

Thereafter, the semiconductor substrate 74 is subjected to various processes for forming a multi-layered wiring arrangement thereon, and is then subjected to a dicing process, in which it is cut along the scribe lines, whereby the nonvolatile semiconductor memory devices are separated from each other, resulting in the production of the nonvolatile semiconductor memory devices, each of which may be referred to as a first embodiment of the nonvolatile semiconductor memory device according to the present invention.

As is apparent from the foregoing, according to the present invention, it is possible to manufacture the nonvolatile semiconductor memory devices including a plurality of memory cells, each of which features a tunnel window having a dimension or diameter of less than 0.4 μm. In other words, according to the present invention, it is possible to considerably diminish a possible dimension or diameter of the tunnel windows.

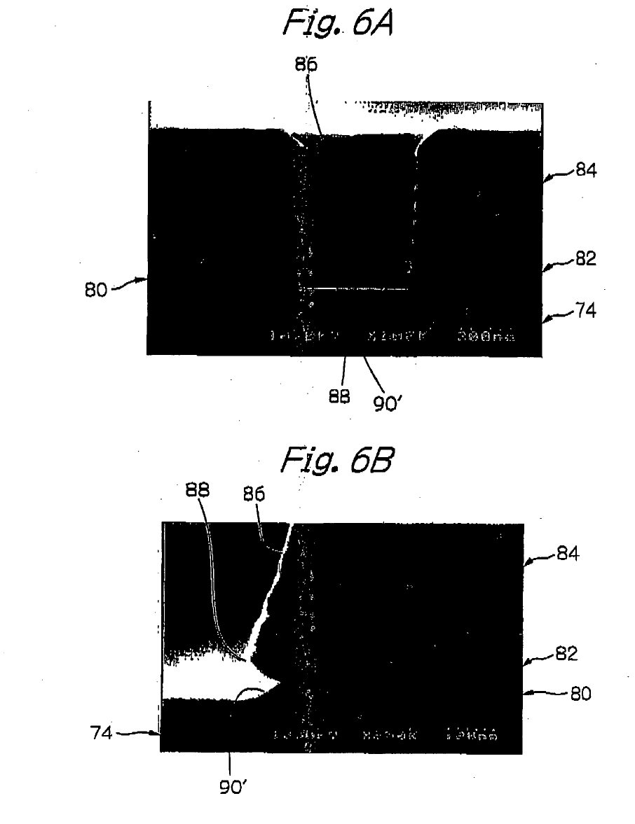

FIGS. 6A and 6B show electron microscope photographs of an intermediate product of a FLOTOX type nonvolatile semiconductor memory device manufactured in accordance with the according to the present invention. Note, FIG. 6B shows a partially-enlarged photograph of the electron microscope photograph of FIG. 6A.

The electron microscope photograph of FIG. 6A corresponds to the cross-sectional view shown in FIG. 5E, and the features similar to those of FIG. 5E are indicated by the same references in FIGS. 6A and 6B. As is apparent from the electron microscope photograph of FIG. 6A, the tunnel windows 90′ have a dimension or diameter of 0.3 μm which is approximately equivalent to a scale (300 nm) represented by eleven small aligned white dots, with a space between two adjacent white dots representing a length of 30 nm. Note, of course, in the above-mentioned first and second prior art production methods, a tunnel window having a dimension or diameter of 0.3 cannot be formed in a silicon dioxide layer on a silicon substrate.

Note, in this first embodiment, although the tunnel window is formed on the drain region 78, it may be formed on the source region 76.

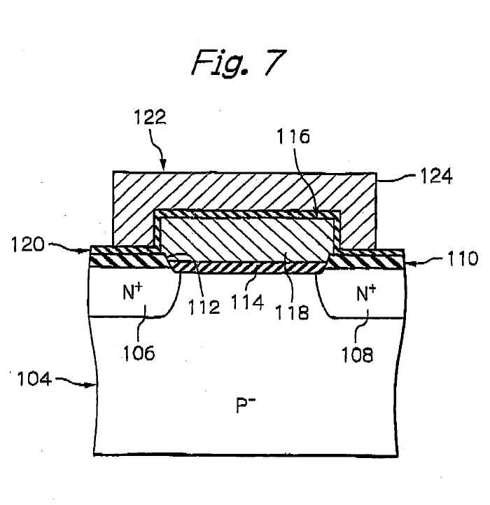

FIG. 7 shows a semiconductor substrate of another FLOTOX type nonvolatile semiconductor memory device, which may be manufactured by the production method according to the present invention, and which may be referred to as a second embodiment of the nonvolatile semiconductor memory device according to the present invention.

In this second embodiment of the nonvolatile semiconductor memory device, the semiconductor substrate is indicated by reference 104. Similar to the first embodiment of the nonvolatile semiconductor device, the semiconductor substrate 104 is derived from a monocrystalline silicon wafer, and a surface of the semiconductor substrate 104 is sectioned into a plurality of chip areas by forming grid-like fine grooves (i.e. scribe lines) therein. Also, a plurality of element-isolation layers (not shown) are formed in each of the chip areas on the semiconductor substrate 104 by using a TSI method or a LOCOS method, so that a plurality of element-formation areas are defined on a surface of each of the chip areas. Note, in FIG. 7, one of the element-formation areas, which forms a part of a memory cell to be produced in the semiconductor substrate 104, is partially illustrated in a cross-sectional view.

After the definition of the element-formation areas in each of the chip areas is completed, as shown in FIG. 7, a source region 106 and a drain region 108 are formed in each of the element-formation areas of the semiconductor substrate 104 by using various well-known processes. Then, a silicon dioxide layer 110 is formed on the semiconductor device. Then, a plurality of tunnel windows 112 are formed in the silicon dioxide layer 110 in substantially the same manner as stated with reference to FIGS. 5D and 5E. Note, in this second embodiment, the formation of the tunnel windows 112 is carried out such that a channel region between the adjacent source and drain regions 106 and 108 is exposed by each of the tunnel windows 112.

After the formation of the tunnel windows 112 is completed, a silicon dioxide layer 114 is formed as a tunnel insulating layer on each of the channel regions on the semiconductor substrate 104, in substantially the same manner as stated with reference to FIG. 5F, so as to bridge a space between the adjacent source and drain regions 106 and 108.

After the formation of the tunnel insulating layers 114 is completed, a polycrystalline silicon layer 116 is formed on the silicon dioxide layer 110 including the tunnel insulating layers 114, by using a suitable CVD process, and then suitable impurities are implanted and diffused in the polycrystalline silicon layer 116, by using various well-known processes. Then, the polycrystalline silicon layer 116 is patterned by using a photolithography process and an etching process, so that a plurality of floating gate electrodes 118 are defined on the silicon dioxide layer 110 including the tunnel insulating layers 114. Each of the floating gate electrodes 118 is positioned so as to be in contact with a corresponding channel region through the intermediary of a corresponding tunnel insulating layer 114.

After the definition of the floating gate electrodes 118 is completed, an insulating interlayer 120 is formed over the silicon dioxide layer 110 and the floating gate electrodes 118. The insulating interlayer 120 may be defined as a multi-layered insulating layer composed of a first silicon dioxide layer section, a silicon nitride layer section, and a second silicon dioxide layer formed in order on the silicon dioxide layer 110 and the floating gate electrodes 118. Note, it is possible to carry out the formation of the multi-layered insulating interlayer 120 by using a suitable CVD process.

After the formation of the insulating interlayer 120 is completed, a polycrystalline silicon layer 122 is further formed over the insulating interlayer 120 by using a suitable CVD process, and then suitable impurities are implanted and diffused in the polycrystalline silicon layer 122, by using various well-known processes. Then, the polycrystalline silicon layer 122 is patterned by using a photolithography process and an etching process, so that a plurality of control gate electrodes 124 are defined on the insulating interlayer 120. Each of the control gate electrodes 124 is positioned so as to cover a corresponding floating gate electrode 118. Note, in FIG. 5H, only one of the control gate electrodes 102 is representatively illustrated.

Thereafter, the semiconductor substrate 104 is subjected to various processes for forming a multi-layered wiring arrangement thereon, and is then subjected to a dicing process, in which it is cut along the scribe lines, whereby the nonvolatile semiconductor memory devices are separated from each other, resulting in the production of the nonvolatile semiconductor memory devices.

Of course, in the second embodiment, it is possible to manufacture the nonvolatile semiconductor memory devices including a plurality of memory cells, each of which features a tunnel window having a dimension or diameter of less than 0.4 μm.

In the second embodiment shown in FIG. 7, although the tunnel window 112 has a size so that the channel region between the adjacent source and drain regions 106 and 108 is entirely exposed, it may have a small size so that the channel region between the adjacent source and drain regions 106 and 108 is partially exposed.

In the above-mentioned embodiments of the present invention, although the floating gate electrodes (96, 118) and the control gate electrodes (102, 124) are composed of a polycrystalline silicon material, each of these electrodes may be of another conductive material, such as an amorphous silicon material, a suitable metal material or the like.

Also, in the above-mentioned embodiments of the present invention, it is possible to substitute an N⁻-type semiconductor substrate for the P⁻-type semiconductor substrate (10, 104). Of course, in this case, each of the source region (76, 106) and the drain region (78, 108) is produced as a p⁺-type region.

Finally, it will be understood by those skilled in the art that the foregoing description is of preferred embodiments of the process and the device, and that various changes and modifications may be made to the present invention without departing from the spirit and scope thereof.

1. A semiconductor device comprising:
a semiconductor substrate; and
an oxide layer formed on said semiconductor substrate, said oxide layer having a window which is formed by
forming a peeling-prevention layer on said oxide layer, said peeling-prevention layer exhibiting a superior adhesion property to said oxide layer,
forming a KrF-ray sensitive photoresist layer on said peeling-prevention layer, said peeling-prevention layer exhibiting a superior adhesion property to said KrF-ray sensitive photoresist layer,
forming an opening in said KrF-ray sensitive photoresist layer,
performing an anisotropic etching process by using said KrF-ray sensitive photoresist layer as a mask, so that an opening and a recess are respectively formed in said peeling-prevention layer and said oxide layer, and
performing a wet etching process by using said peeling-prevention layer as a mask without being subjected to damage, resulting in formation of the recess of said oxide layer as said window in said oxide layer, whereby a surface area of said semiconductor substrate is exposed by said window.

2. The semiconductor device as set forth in claim 1, wherein the opening of said KrF-ray sensitive photoresist layer features a dimension of less than 0.3 μm, and wherein said window features a dimension of less than 0.4 μm.

3. The semiconductor device as set forth in claim 1, wherein the formation of said peeling-prevention layer is carried out by using a composite resin material which is composed of a polyimide-based polymer component, and a dye component selected from a group consisting of an organic halogen compound, a hydroxyl compound, and a carboxyl compound.

4. The semiconductor device as set forth in claim 1, wherein the formation of said peeling-prevention layer is carried out by using a polymer material which is obtained from a triazine-based derivative.

5. A production method for manufacturing a semiconductor device, which comprises:
preparing a semiconductor substrate;
forming an oxide layer, on said semiconductor substrate;
forming a peeling-prevention layer on said oxide layer, said peeling-prevention layer exhibiting a superior adhesion property to said oxide layer;
forming a KrF-ray sensitive photoresist layer on said peeling-prevention layer, said peeling-prevention layer exhibiting a superior adhesion property to said KrF-ray sensitive photoresist layer;
forming an opening in said KrF-ray sensitive photoresist layer;
performing an anisotropic etching process by using said KrF-ray sensitive photoresist layer as a mask, so that an opening and a recess are formed in said peeling-prevention layer and said oxide layer, respectively; and
performing a wet etching process by using said peeling-prevention layer as a mask, so that the recess of said oxide layer is formed as a window in said oxide layer, whereby a surface area of said semiconductor substrate is exposed by said window.

6. The production method as set forth in claim 5, wherein the opening of said KrF-ray sensitive photoresist layer features a dimension of less than 0.3 μm, and wherein said window features a dimension of less than 0.4 μm.

7. The production method as set forth in claim 5, wherein the formation of said peeling-prevention layer is carried out by using a composite resin material which is composed of a polyimide-based polymer component, and a dye component selected from a group consisting of an organic halogen compound, a hydroxyl compound, and a carboxyl compound.

8. The production method as set forth in claim 5, wherein the formation of said peeling-prevention layer is carried out by using a polymer material which is obtained from a triazine-based derivative.

9. A floating gate tunnel oxide type nonvolatile semiconductor memory device comprising:
a semiconductor substrate; and
an oxide layer formed on said semiconductor substrate, said oxide layer having a tunnel window, which is formed by
forming a peeling-prevention layer on said oxide layer, said peeling-prevention layer exhibiting a superior adhesion property to said oxide layer,
forming a KrF-ray sensitive photoresist layer on said peeling-prevention layer, said peeling-prevention layer exhibiting a superior adhesion property to said KrF-ray sensitive photoresist layer,
forming an opening in said KrF-ray sensitive photoresist layer,
performing a wet etching process by using said KrF-ray sensitive photoresist layer as a mask, so that an opening and a recess are respectively formed in said peeling-prevention layer and said oxide layer, and
performing a wet etching process by using said peeling-prevention layer as a mask, resulting in the formation of the recess of said oxide layer as said tunnel window in said oxide layer, whereby a surface area of said semiconductor substrate is exposed by said window; and
a tunnel insulating layer formed on the exposed surface area of semiconductor substrate.

10. The floating gate tunnel oxide type nonvolatile semiconductor memory device as set forth in claim 9, wherein said semiconductor substrate has a drain region formed therein, the exposed surface area of semiconductor substrate forming a part of said drain region.

11. The floating gate tunnel oxide type-nonvolatile semiconductor memory device as set forth in claim 9, wherein said semiconductor substrate has a source region formed therein, the exposed surface area of semiconductor substrate forming a part of said source region.

12. The floating gate tunnel oxide type nonvolatile semiconductor memory device as set forth in claim 9, wherein said semiconductor substrate has a source region, a drain region, and a channel region which are formed therein and associated with each other, the exposed surface area of semiconductor substrate forming said channel region.

13. The floating gate tunnel oxide type nonvolatile semiconductor memory device as set forth in claim 9, further comprising:
a floating gate electrode formed on said tunnel insulating layer;
an insulating interlayer formed on said oxide layer including said floating gate electrode; and
a control gate electrode formed on said insulating interlayer so as to cover said floating gate electrode.

14. The floating gate tunnel oxide type nonvolatile semiconductor memory device as set forth in claim 9, wherein the opening of said KrF-ray sensitive photoresist layer features a dimension of less than 0.3 μm, and wherein said tunnel window features a dimension of less than 0.4 μm.

15. The floating gate tunnel oxide type nonvolatile semiconductor memory device as set forth in claim 9, wherein the formation of said peeling-prevention layer is carried out by using a composite resin material which is composed of a polyimide-based polymer component, and a dye component selected from a group consisting of an organic halogen compound, a hydroxyl compound, and a carboxyl compound.

16. The floating gate tunnel oxide type nonvolatile semiconductor memory device as set forth in claim 9, wherein the formation of said peeling-prevention layer is carried out by using a polymer material which is obtained from a triazine-based derivative.

17. A production method for manufacturing a floating gate tunnel oxide type nonvolatile semiconductor memory device, which comprises:
preparing a semiconductor substrate;
forming an oxide layer on said semiconductor substrate;
forming a peeling-prevention layer on said oxide layer, said peeling-prevention layer exhibiting a superior adhesion property to said oxide layer;
forming a KrF-ray sensitive photoresist layer on said peeling-prevention layer, said peeling-prevention layer exhibiting a superior adhesion property to said KrF-ray sensitive photoresist layer;
forming an opening in said KrF-ray sensitive photoresist layer;
performing an anisotropic etching process by using said KrF-ray sensitive photoresist layer as a mask, so that an opening and a recess are respectively formed in said peeling-prevention layer and said oxide layer;
performing a wet etching process by using said peeling-prevention layer as a mask, so that the recess of said oxide layer is formed as a tunnel window in said oxide layer, whereby a surface area of said semiconductor substrate is exposed by said tunnel window; and
forming a tunnel insulating layer on the exposed surface area of semiconductor substrate.

18. The production method as set forth in claim 17, wherein said semiconductor substrate has a drain region formed therein, the exposed surface area of semiconductor substrate forming a part of said drain region.

19. The production method as set forth in claim 17, wherein said semiconductor substrate has a source region formed therein, the exposed surface area of semiconductor substrate forming a part of said source region.

20. The production method as set forth in claim 17, wherein said semiconductor substrate has a source region, a drain region, and a channel region which are formed therein and associated with each other, the exposed surface area of semiconductor substrate forming said channel region.

21. The production method as set forth in claim 17, further comprising:
forming a floating gate electrode on said tunnel insulating layer;
forming an insulating interlayer on said oxide layer including said floating gate electrode; and
forming a control gate electrode on said insulating interlayer so as to cover said floating gate electrode.

22. The production method as set forth in claim 17, wherein the opening of said KrF-ray sensitive photoresist layer features a dimension of less than 0.3 μm, and wherein said tunnel window features a dimension of less than 0.4 μm.

23. The production method as set forth in claim 17, wherein the formation of said peeling-prevention layer is carried out by using a composite resin material which is composed of a polyimide-based polymer component, and a dye component selected from a group consisting of an organic halogen compound, a hydroxyl compound, and a carboxyl compound.

24. The production method as set forth in claim 17, wherein the formation of said peeling-prevention layer is carried out by using a polymer material which is obtained from a triazine-based derivative.
